(19) United States
(12) Patent Application Publication
(10) Pub. No.: US 2011/0017254 A1
(43) Pub. Date: Jan. 27, 2011

(54) THERMOELECTRIC MODULES WITH IMPROVED CONTACT CONNECTION

(75) Inventors: Madalina Andreea STEFAN, Ludwigshafen (DE); Stephan Hermes, Bad Duerkheim (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, Ludwigshafen (DE)

(21) Appl. No.: 12/842,453

(22) Filed: Jul. 23, 2010

(30) Foreign Application Priority Data
Jul. 27, 2009 (EP) 09166446.6

(51) Int. Cl. H01L 35/08; H01L 35/34; H01R 43/02

(52) U.S. Cl. 136/230; 29/879; 136/201

(57) ABSTRACT

What is described is a thermoelectric module composed of p- and n-conductive thermoelectric material legs which are connected to one another alternately via electrically conductive metallic contacts, wherein the electrically conductive metallic contacts are connected to the thermoelectric material legs by hard soldering or high-temperature soldering with a solder comprising metal and glass.

The invention relates to thermoelectric modules with improved connection of the thermoelectric material legs to electrically conductive contacts.

Thermoelectric generators and Peltier arrangements as such have been known for some time. p- and n-doped semiconductors which are heated on one side and cooled on the other side transport electrical charges through an external circuit, and electrical work can be performed by a load in the circuit. The efficiency of conversion of heat to electrical energy achieved in this process is limited thermodynamically by the Carnot efficiency. Thus, at a temperature of 1000 K on the hot side and 400 K on the “cold” side, an efficiency of (1000-400): 1000=60% would be possible. However, only efficiencies of up to 6% have been achieved to date.

On the other hand, when a direct current is applied to such an arrangement, heat is transported from one side to the other side. Such a Peltier arrangement works as a heat pump and is therefore suitable for cooling apparatus parts, vehicles or buildings. Heating via the Peltier principle is also more favorable than conventional heating, because more heat is always transported than corresponds to the energy equivalent supplied.

A good overview of effects and materials is given, for example, by S. Nolan et al., Recent Developments in Bulk Thermoelectric Materials, MRS Bulletin, vol. 31, 2006, pages 199 to 206.

At present, thermoelectric generators are used in space probes for generating direct currents, for cathodic corrosion protection of pipelines, for energy supply to light buoys and radio buoys and for operating radios and television sets. The advantages of thermoelectric generators lie in their extreme reliability. For instance, they work irrespective of atmospheric conditions such as air humidity; there is no fault-prone mass transfer, but rather only charge transfer; the fuel is combusted continuously, and catalytically without a free flame, as a result of which only small amounts of CO, NOₓ and uncombusted fuel are released; it is possible to use any fuels from hydrogen through natural gas, gasoline, kerosene, diesel fuel up to biologically obtained fuels such as rapeseed oil methyl ester.

Thermoelectric energy conversion thus fits extremely flexibly into future requirements such as hydrogen economy or energy generation from renewable energies.

A thermoelectric module consists of p- and n-legs, which are connected electrically in series and thermally in parallel. FIG. 1 shows such a module.

The conventional construction consists of two ceramic plates between which the individual legs are arranged in alternation. Every two legs are conductively connected to electrical contacts via the end faces.

In addition to the electrically conductive contacting, different further layers are normally also applied to the actual material, which serve as protective layers or as solder layers. Ultimately, electrical contact is established between two legs, however, via a metal bridge.

An essential element of thermoelectric components is the contact connection. The contact connection establishes the physical connection between the material in the “heart” of the component (which is responsible for the desired thermoelectric effect of the component) and the “outside world”. The structure of such a contact connection is shown schematically in FIG. 2.

The thermoelectric material 1 within the component is responsible for the actual effect of the component. This is a thermoelectric leg. An electrical current and a thermal current flow through the material 1, in order that it fulfills its purpose in the overall structure.

The material 1 is connected to the supply lines 6 and 7 via the contacts 4 and 5, on at least two sides. The layers 2 and 3 are intended to symbolize one or more intermediate layers which may be necessary (barrier material, solder, adhesion promoter or the like) between the material 1 and the contacts 4 and 5. The segments 2/3, 4/5, 6/7, each of which correspond to one another in pairs, however, need not be identical. This depends ultimately on the specific structure and the application, just as the flow direction of electrical current or thermal current results from the structure.

An important role is assumed by the contacts 4 and 5. These ensure a close connection between material and supply line. When the contacts are poor, high losses occur here, which can severely restrict the performance of the component. For this reason, the contacts are frequently pressed onto the material. The contacts are thus subjected to high mechanical stress. This mechanical stress increases as soon as elevated (or else reduced) temperatures or/and thermal cycling play a role. The thermal expansion of the materials incorporated into the component leads inevitably to mechanical stress, which leads in the extreme case to failure of the component as a result of detachment of the contact.

In order to prevent this, the contacts used must have a good connection to the thermoelectric material legs and preferably also a certain flexibility and spring properties, in order that such thermal stresses can be balanced out.

### BRIEF DESCRIPTION OF THE DRAWINGS

FIG. 1 shows a thermoelectric module which consists of p- and n-legs which are connected electrically in series and thermally in parallel.

FIG. 2 shows a contact connection which establishes the physical connection between the material in the heart of the component and the outside world.

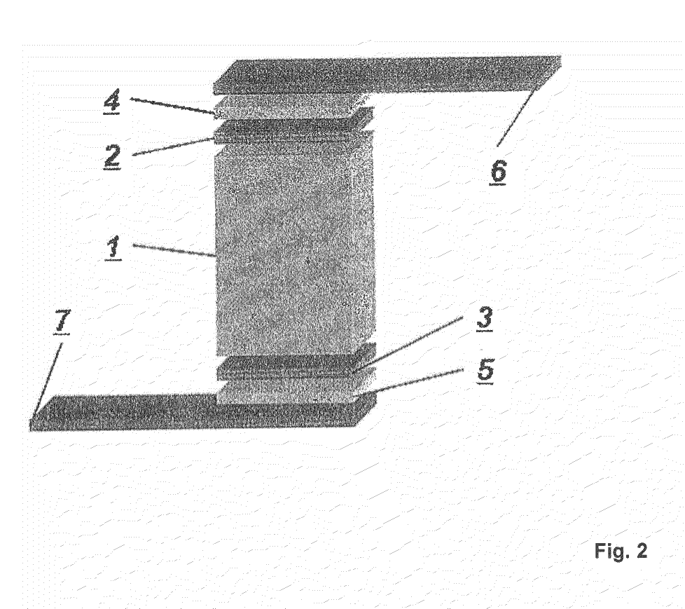

FIG. 3 shows a TEM image of the silver-soldered joint obtained according to the present invention.

In order to impart stability to the whole structure and ensure the necessary, substantially homogeneous thermal coupling over the total number of legs, carrier plates are needed. For this purpose, a ceramic is typically used, for example composed of oxides or nitrides such as Al₂O₃, SiO₂ or AlN.

This typical structure entails a series of disadvantages. The ceramic and the contacts are only of limited mechanical durability. Mechanical and/or thermal stresses can easily lead to cracks or breakdown of the contact connection, which makes the entire module unusable.

The contacts and the connection of the contacts to the thermoelectric material legs has to fulfill numerous tasks in order to ensure connection with low electrical resistance and high thermal stability, and also high mechanical stability:

The electrode material must be chemically stable in contact with the thermoelectric material under operating conditions.

The formation of a connection site shall not lead to an intermediate layer with high electrical resistivity or reduced electron carrier density.

When connection is effected by soldering, the electrodes and the thermoelectric material should have coefficients of thermal expansion matched to one another, in order to avoid shear stresses under thermal stress.

In the case of soldered electrodes, it has to be ensured that the solder cannot diffuse into the thermoelectric material and poison it, especially when the connection is operated at relatively high temperatures.

Thermoelectric modules based on PbTe can be operated at temperatures of up to about 600° C., which leads to a higher efficiency compared to, for example, Bi₂Te₃-based thermoelectric materials which can be operated only at temperatures of below 300° C. The high-temperature applications of PbTe modules place increased demands on the electric volume resistance and the thermal stability of the connection between contact and thermoelectric material leg.

Long-term stability of the thermoelectric modules can be achieved only when the mechanical and chemical stability of the thermoelectric material legs, of the electrical contacts and of the connection thereof are ensured under operating conditions.

Electrical contact connections for PbTe material legs are described, for example, in N. Elsner, Mat. Res. Soc. Symp. Proc. Vol. 234, 1991, pages 167 to 177. It is possible to distinguish contact connections which require a continuous pressing force in order to exhibit a low contact resistance, metallurgical connections and mechanical connections. All connection techniques mentioned have their advantages and disadvantages. Contacts which require a continuous pressing force are not practicable in all applications and are complex in terms of construction, since specific constructions are required to ensure the pressing force. However, only low mechanical stresses are generated at the transition between thermoelectric material and contact.

Metallurgical and mechanical bonds which are generated between thermoelectric material legs and contact materials typically use an intermediate layer which acts as a chemical barrier against contamination and/or degradation of the thermoelectric material as a result of metal doping. The customary intermediate layers for PbTe material legs are, for example, SnTe, graphite or lead foils.

For inexpensive production of thermoelectric modules, the construction methods are costly and inconvenient. The present invention enables less expensive and, as a result of fewer layers to be applied, fewer working steps in the module production.

Soldering is the most commonly used connection process for Bi₂Te₃ modules, which are operated only at low temperatures of below 300° C. For high-temperature applications, hard solders based on copper or silver alloys are available. For PbTe, however, without additional protective layers, it is impossible to use copper-based solders since copper poisons PbTe and forms a eutectic mixture with a melting point of 500° C., which reduces the actual melting point of PbTe of 922° C. Silver-based solder is therefore the only remaining high-temperature solder for PbTe. Silver is, however, a p-type dopant of PbTe, and silver-based solder also diffuses into PbTe when the thermoelectric materials are exposed to temperatures above 400° C.

It is an object of the present invention to provide thermoelectric modules which exhibit improved connection of electrically conductive contacts to thermoelectric material legs, ensuring both mechanical stability and chemical stability, such that the thermoelectric material is not contaminated with other chemical substances.

The object is achieved in accordance with the invention by a thermoelectric module composed of p- and n-conductive thermoelectric material legs which are connected to one another alternately via electrically conductive metallic contacts, wherein the electrically conductive metallic contacts are connected to the thermoelectric material legs by hard soldering or high-temperature soldering with a solder comprising metal and glass.

It has been found in accordance with the invention that a solder comprising metal and glass leads to an advantageous connection of electrically conductive metallic contacts to thermoelectric material legs. The contacts obtained are thermally, chemically and mechanically stable. An in situ diffusion barrier is formed, such that solder metals, especially silver, cannot diffuse into the thermoelectric materials. At the same time, an excellent electrical conductivity is ensured between the thermoelectric material leg and the metal contact. Use of an inventive silver-containing solder allows silver to be used as the electric contact material for PbTe materials too. In addition, the solder achieves very good adhesion between thermoelectric material legs and metallic contacts.

The metal in the solder may be selected from any suitable metals which allow hard soldering or high-temperature soldering.

Different soldering methods are distinguished according to the liquefaction temperature of the solder. At temperatures up to 450° C., reference is made to soft solders, at temperatures above 450° C. to hard solders, at temperatures above 900° C. to high-temperature solders; see also DIN 8505 part 2.

Solder metals used in accordance with the invention thus allows soldering at temperatures above 450° C., especially above 700° C.

The metal in the solder is preferably selected from silver and copper or alloys thereof. Particular preference is given to silver as the solder material.

In addition to one or more metals or metal alloys, the solder comprises glass. The glass content in the solder is preferably 0.1 to 20% by weight, more preferably 0.01 to 10% by weight, especially 1 to 5% by weight, based on the overall solder. The glass may be any suitable glass. It is preferably fritted glass or glass frits. The glass is preferably present in the solder in the form of particles having a mean particle size in the range from 100 nm to 10 μm, more preferably 0.5 to 5 μm.

The glass is an inorganic glass. The inorganic glass may be SiO₂, Al₂O₃, Bi₂O₃, ZnO, PbO, AgO, CuO, FeO, SrO, CaO, MgO, ZrO₂, TeO₂, SnO₂, TiO₂, Li₂O, Na₂O, K₂O, MoO₃, BO₃, Fe₂O₃, Le₂O₃, Nb₂O₅, Sb₂O₅, or mixtures thereof. The glass more preferably comprises SiO₂ and Al₂O₃ as inorganic base components. In addition, the material may comprise a metal which is oxidized in the course of hard soldering, which removes the residual oxygen at the bonding site, before the thermoelectric material forms its own oxide layer and gives a relatively high contact resistance.

The solder may consist only of metal (including metal mixtures or metal alloys) and glass. However, it may also comprise further ingredients typical of solders, for example fluxes or antioxidants. In one embodiment of the invention, the solder additionally comprises organic polymers, organometallic compounds, organic solvents or mixtures thereof as additives. The use of organometallic compounds can lead to stronger connection of the solder, for example on PbTe, and bring about improved sintering performance of the silver particles.

In principle, all dispersants which are known to those skilled in the art for use in dispersions and are described in the prior art are suitable. Preferred dispersants are surfactants or surfactant mixtures, for example anionic, cationic, amphoteric or nonionic surfactants. Cationic and anionic surfactants are described, for example, in Encyclopedia of Polymer Science and Technology, J. Wiley & Sons (1966), Volume 5, pages 816 to 818, and in Emulsion Polymerisation and Emulsion Polymers, editors: P. Lovell and M. El-Asser, Verlag Wiley & Sons (1997), pages 224 to 226. However, it is also possible to use polymers which are known to those skilled in the art and have pigment-affinitive anchor groups as dispersants. In addition, it is possible to use further additives such as thixotropic agents, for example organic thixotropic agents and thickeners, for example polyacrylic acid, polyurethanes, hydrogenated castor oil, plasticizers, wetting agents, defoamers, desiccants, thickeners, complexing agents, conductive polymer particles.

The thickness of the solder layer is not restricted in accordance with the invention. The thickness of the solder layer is preferably 10 nm to 500 μm, especially 1 to 100 μm.

The production of the solder is possible by mixing of starting powders composed of metal and glass, and subsequent co-melting. It is also possible to mix the glass particles into the molten solder.

Hard soldering or high-temperature soldering is known per se and can be performed by known processes. Hard soldering is preferably performed under inert conditions. If inert conditions are impossible or too costly and inconvenient, a metal can be added to the solder, which reacts to give the corresponding metal oxide by in situ oxidation during the hard soldering or heating, which removes the residual oxygen from the contact site.

The thermoelectric materials present in the thermoelectric material legs can be selected freely. Suitable materials are described in the Nolan reference cited above. Particular preference is given to using a PbTe-based thermoelectric material. This material comprises, as the main constituent, PbTe as well as p- or n-dopants.

The electrically conductive metallic contacts may be selected from any desired suitable metals. The contacts preferably have very good electrical conductivity, examples being those composed of copper or silver, especially of silver.

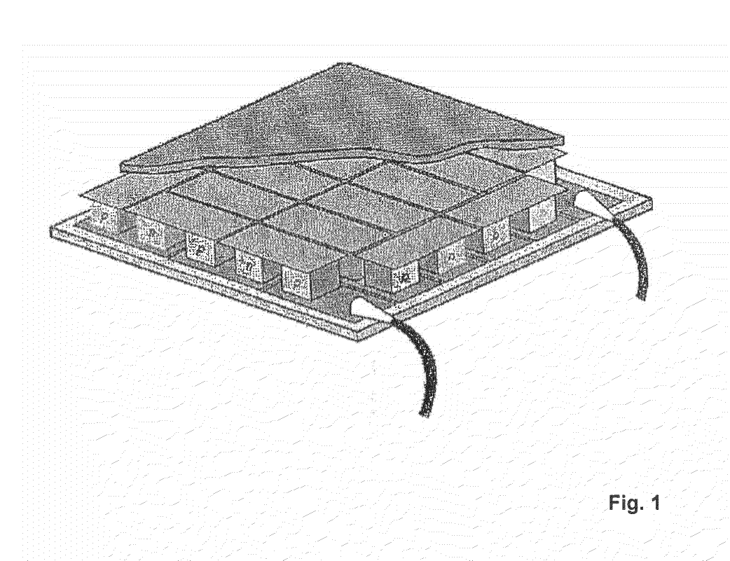

The electrically conductive contacts may have any desired suitable geometry. A suitable geometry is shown, for example, in FIG. 1.

The electrically conductive contacts on the cold and/or warm side of the thermoelectric module may have, between the thermoelectric material legs, in the profile thereof, at least one flexibility site which allows bending and slight shifting of the thermoelectric material legs with respect to one another.

The expression “flexibility site” describes a site in the profile of the electrical contact which allows bending or shifting of the contact connected to the p-leg and n-leg. The two material legs should be displaceable slightly with respect to one another. The word “slightly” describes a displacement by a maximum of 20%, more preferably by a maximum of 10%, of the distance between the particular p- and n-conductive, thermoelectric material legs. The possibility of bending ensures that the contact connection of none of the material legs breaks off when the thermoelectric material is adjusted to a nonplanar surface.

Bending should preferably be possible by an angle of not more than 45°, more preferably not more than 20°, without the contact connection of the thermoelectric material legs breaking off.

The flexibility site may have any desired suitable form, provided that the function described above is fulfilled. The flexibility site is preferably in the form of at least one U-shaped, V-shaped or rectangular bulge in the particular contact. There is more preferably a U-shaped, V-shaped or rectangular bulge in the particular contact.

Alternatively, the flexibility site may preferably be present in the form of a corrugation or spiral, or in sawtooth form, in the particular contact.

The design of the thermoelectric material legs with a flexibility site allows a nonplanar arrangement of the legs and hence, for example, the spiral winding of the thermoelectric module onto a tube of any cross section. The cross sections may be rectangular, round, oval or other cross sections.

The electrically conductive contacts may be formed from any suitable materials. They are typically formed from metals or metal alloys, for example iron, nickel, aluminum, platinum, copper, silver or other metals. Sufficient thermal stability of the metal contact connection should be ensured, since the thermoelectric modules are frequently exposed to high temperatures.

The mechanical stability can be increased further by embedding the thermoelectric material legs into a solid, electrically nonconductive matrix material.

In order to keep the thermoelectric material stable in a desired shape, it is advisable to use a matrix or a grid to stabilize the thermoelectric module. For this purpose, preference is given to using materials with low thermal conductivity and zero electrical conductivity. Examples of suitable materials are aerogels, ceramics, particularly foam ceramics, glass wool, glass ceramic mixtures, electrically insulated metal grids, mica or a combination of these materials. For the temperature range up to 400° C., it is also possible to use synthetic carbon-based polymers such as polyurethanes, polystyrene, polycarbonate, polypropylene, or naturally occurring polymers such as rubber. The matrix materials can be used as a powder, as a shaped body, as a suspension, as a paste, as a foam or as a glass. Heat treatment or irradiation can cure the matrix, as can evaporation of the solvents or crosslinking of the materials used. The matrix can be adjusted to the appropriate application by shaping before use, or be cast, sprayed, knife-coated or applied on application.

The thermoelectric material legs may already be introduced into the matrix material and spatially prepositioned thereby before the contact connection.

The invention also relates to a process for producing thermoelectric modules as described above, in which the solder comprising metal and glass is applied to the thermoelectric material legs and/or the electrically conductive metallic contacts, and thermoelectric material legs and electrically conductive metallic contacts are then bonded at temperatures above 450° C. with melting of the solder.

The thermoelectric material legs may be embedded, before the hard soldering or high-temperature soldering, in a solid, electrically nonconductive matrix material. The thermoelectric material legs and electrically conductive metallic contacts and optionally the matrix material, before the hard soldering or high-temperature soldering, can also be clamped between two electrically nonconductive substrate plates, such that thermoelectric material legs, electrically conductive metallic contacts and if appropriate the matrix can be kept in shape by the clamping to the substrates. The entire composite can then be subjected to a thermal treatment for hard soldering or high-temperature soldering.

The hard soldering can also be performed under inert conditions. The hard soldering can alternatively be effected under air and with addition to the hard solder of a metal which is oxidized under hard soldering conditions before the thermoelectric material forms an oxide layer.

The inventive thermoelectric generators or Peltier arrangements generally widen the available range of thermoelectric generators and Peltier arrangements. By varying the chemical composition of the thermoelectric generators or Peltier arrangements, it is possible to provide different systems which satisfy different requirements in a multitude of possible applications. The inventive thermoelectric generators or Peltier arrangements thus widen the range of application of these systems.

The present invention also relates to the use of an inventive thermoelectric generator or of an inventive Peltier arrangement
as a heat pump
for climate control of seating furniture, vehicles and buildings
in refrigerators and (laundry) dryers
for simultaneous heating and cooling of streams in processes for
substance separation such as
   absorption
   drying
   crystallization
   evaporation
   distillation
as a generator for utilization of heat sources such as
   solar energy
   geothermal heat
   heat of combustion of fossil fuels
   waste heat sources in vehicles and stationary units
   heat sinks in the evaporation of liquid substances
   biological heat sources
for cooling electronic components.

The present invention further relates to a heat pump, to a refrigerator, to a (laundry) drier or to a generator for utilizing heat sources, comprising at least one inventive thermoelectric generator or one inventive Peltier arrangement, by means of which, in the case of the (laundry) drier, a material to be dried is heated directly or indirectly and by means of which the water or solvent vapor obtained in the drying is cooled directly or indirectly.

The invention is illustrated in detail with reference to an example.

### EXAMPLE

Doped p- and n-type PbTe material legs were produced from a PbTe fusion product. A thin layer of silver-glass solder was knife-coated in a thickness of 100 μm onto the PbTe legs at room temperature under inert conditions. The solder was obtained by mixing silver with glass particles having a mean particle diameter in the range from 0.5 to 5 μm. The glass content was 3%. Then silver electrodes were applied, and the arrangement obtained was clamped between two electrically insulating ceramic plates. The arrangement was then heated to a temperature of 700° C. in an oven, kept at this temperature for 10 minutes and, after the subsequent cooling, removed again from the oven.

In a second experiment, the thermoelectric legs were introduced into a high-temperature-stable matrix of zirconium oxide, which served both for mounting of the thermoelectric material legs and for protection against sublimation, diffusion and contamination from the outside. During the hard soldering, a slight pressure can be exerted on the thermoelectric legs. A pressure of 1 MPa (150 psi) was recognized to be sufficient.

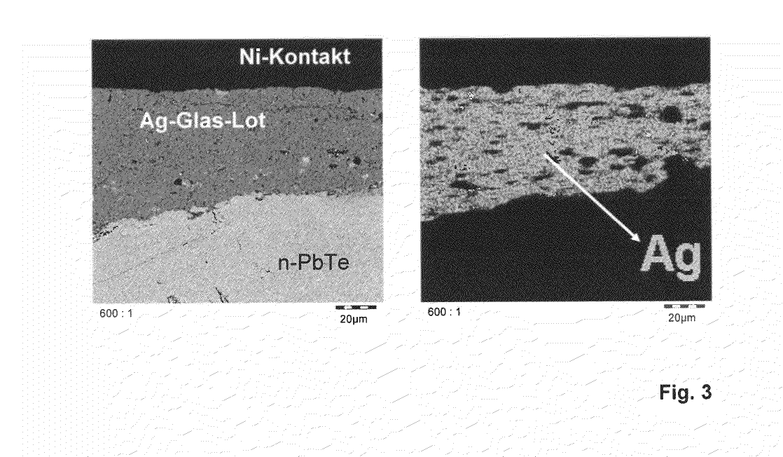

The silver-soldered joint obtained according to the present invention is shown in FIG. 3. The two arrows on the left show silver crystals in the TEM image, while the right-hand arrow denotes a glass interface.

1. A thermoelectric module composed of p- and n-conductive thermoelectric material legs which are connected to one another alternately via electrically conductive metallic contacts, wherein the electrically conductive metallic contacts are connected to the thermoelectric material legs by hard soldering or high-temperature soldering with a solder comprising metal and glass.

2. The thermoelectric module according to claim 1, wherein the metal in the solder is selected from silver and copper or alloys thereof.

3. The thermoelectric module according to claim 1, wherein the glass in the solder is present in the form of particles having a mean particle size in the range from 100 nm to 10 μm.

4. The thermoelectric module according to claim 1, wherein the glass content in the solder is 0.1 to 20% by weight, based on the overall solder.

5. The thermoelectric module according to claim 1, wherein the glass is present in the solder in the form of fritted glass.

6. The thermoelectric module according to claim 1, wherein the solder thickness is 10 nm to 500 μm.

7. The thermoelectric module according to claim 1, wherein the solder additionally comprises organic polymers, organometallic compounds, organic solvents or mixtures thereof as additives.

8. The thermoelectric module according to claim 1, wherein the thermoelectric material legs are embedded into a solid, electrically nonconductive matrix material.

9. A process for producing thermoelectric modules according to claim 1, which comprises applying the solder comprising metal and glass to the thermoelectric material legs and/or the electrically conductive metallic contacts, and then bonding thermoelectric material legs and electrically conductive metallic contacts at temperatures above 450° C. with melting of the solder.

10. The process according to claim 9, wherein the thermoelectric material legs, before the hard soldering or high-temperature soldering, are embedded in a solid, electrically nonconductive matrix material.

11. The process according to claim 9, wherein the thermoelectric material legs and electrically conductive metallic contacts and optionally the matrix material, before the hard soldering or high-temperature soldering, are clamped between two electrically nonconductive substrate plates.

12. The process according to claim 9, wherein the hard soldering is performed under inert conditions.

13. The process according to claim 9, wherein the hard soldering is effected under air and with addition to the hard solder of a metal which is oxidized under hard soldering conditions before the thermoelectric material forms an oxide layer.

14. Heat pumps, refrigerators, dryers or generators, containing the thermoelectric modules according to claim 1.
